(19) United States
(12) Patent Application Publication
(10) Pub. No.: US 2010/0214745 A1
(43) Pub. Date: Aug. 26, 2010

(54) HEAT SINK ANCHOR ASSEMBLED ON A PRINTED CIRCUIT BOARD

(75) Inventor: DE-JIN CHEN, Shenzhen (CN)

Correspondence Address: WEI TE CHUNG;FOXCONN INTERNATIONAL, INC., 1650 MEMOREX DRIVE, SANTA CLARA, CA, 95050, US

(73) Assignee: HON HAI PRECISION INDUSTRY CO., LTD., Tu-Cheng (TW)

(21) Appl. No.: 12/711,248

(22) Filed: Feb. 23, 2010

(30) Foreign Application Priority Data
Feb. 24, 2009 (CN) 200920300829.8

(51) Int. Cl. H05K 7/20; F16B 21/18

(52) U.S. Cl. 361/720; 411/522

(57) ABSTRACT

An anchor for attaching a heat sink to a PCB (printed circuit board) includes an elastic fastening member and a locking member. The fastening member includes a resilient link portion, a pair of legs extending from two opposite ends of the resilient link portion, a pair of projections extending inwardly from tip ends of the two legs and a pair of stop portions extending from the legs and spaced from the respective projection. The projections pass through a pair of through holes defined in the PCB respectively until each stop portion abutting against a top surface of PCB. The locking member defines at least one receiving hole. the locking member is mounted onto the fastening member to shift the two leg inward so that the projections abut against a bottom surface of the PCB.

### BACKGROUND OF THE INVENTION

1. Field of the Invention

The present invention relates to a heat sink anchor assembled on a printed circuit board to retain a heat sink.

2. Description of Related Art

U.S. Pat. No. 6,734,371 issued to Arrigotti on May 11, 2004 discloses an anchoring mechanism for securing a heat sink to a PCB (printed circuit board). The anchoring mechanism includes a link portion, a first leg and a second leg extending from two opposite ends of the link portion. Said two legs pass through corresponding holes defined in the PCB and then are soldered in holes. Each of said legs have a compressible section of hook shaped configuration at a free distal end thereof, which deform inwardly to the hole and then expand outwardly under the PCB The compressible sections are used to support solder material between the anchoring mechanism and the holes. Therefore, it is not easy to remove the anchoring mechanism from the printed circuit board.

Hence, an improved electrical connector is required to overcome the disadvantages of the prior art.

### SUMMARY OF THE INVENTION

Accordingly, an object of the present invention is to provide an improved heat sink anchor which can be easily assembled.

In order to achieve the above-mentioned object, an anchor for attaching a heat sink to a PCB (printed circuit board) comprises an elastic fastening member and a locking member. The fastening member comprises a resilient link portion, a pair of legs extending from two opposite ends of the resilient link portion, a pair of projections extending inwardly from tip end portions of the two legs and a pair of stop portions extending from the legs and spaced from the respective projection. The projections pass through a pair of through holes defined in the PCB respectively until each stop portion abutting against a top surface of PCB. The locking member defines at least one receiving hole. The locking member is mounted onto the fastening member to shift the two leg inward so that the projections abut against a bottom surface of the PCB.

Other objects, advantages and novel features of the present invention will become more apparent from the following detailed description of the present embodiment when taken in conjunction with the accompanying drawings.

### BRIEF DESCRIPTION OF THE DRAWINGS

FIG. 1 is an assembled, perspective view of an anchor assembly according to an embodiment of the present invention;

FIG. 2 is a cross sectional view of the anchor assembly taken along line 2-2 of FIG. 1;

FIG. 3 is an exploded, perspective view of the anchor assembly of FIG. 1;

FIG. 4 is an perspective view of the anchor of another embodiment of the present invention; and

FIG. 5 is an exploded, perspective view of the anchor of FIG. 4.

### DETAILED DESCRIPTION OF THE INVENTION

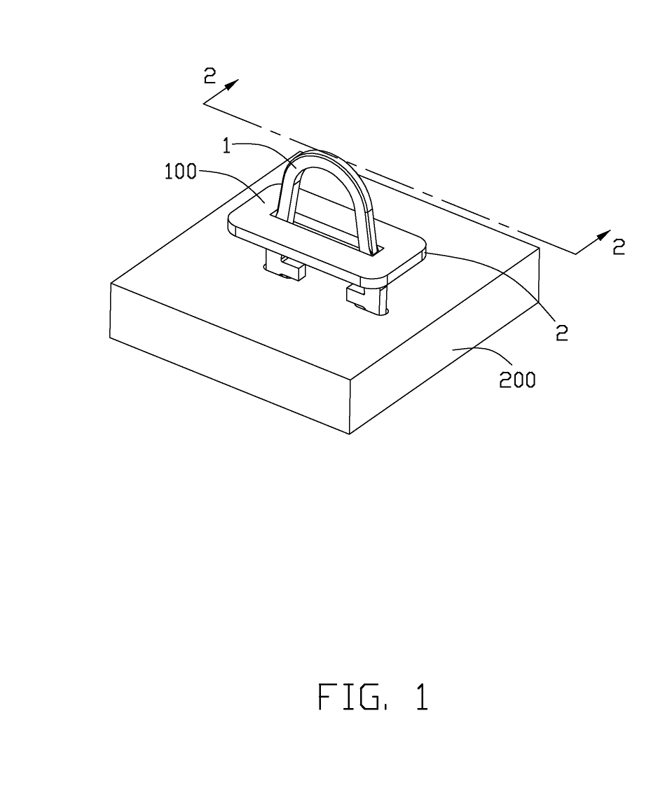

Referring to FIG. 1, an anchor 100 for attaching a heat sink to a PCB (printed circuit board) 200, comprises a fastening member 1 having elasticity and a locking member 2 mounted to the fastening member 1.

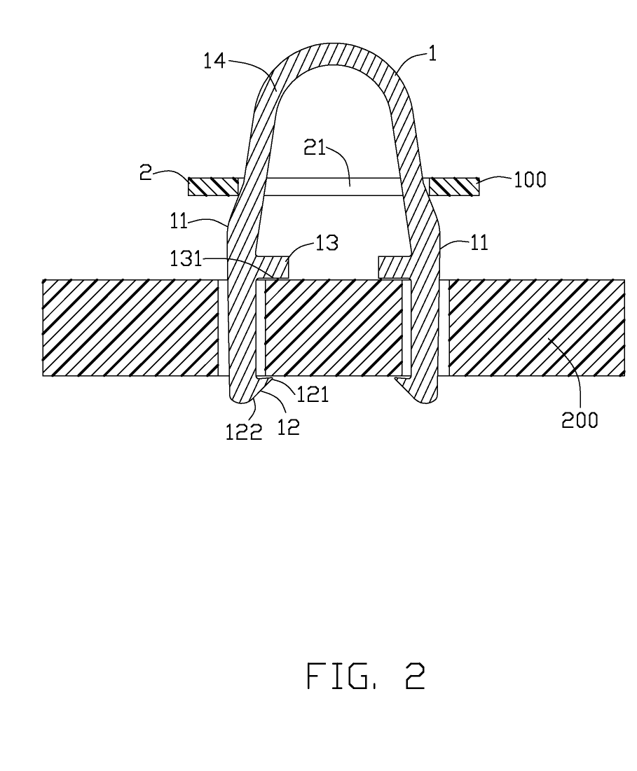

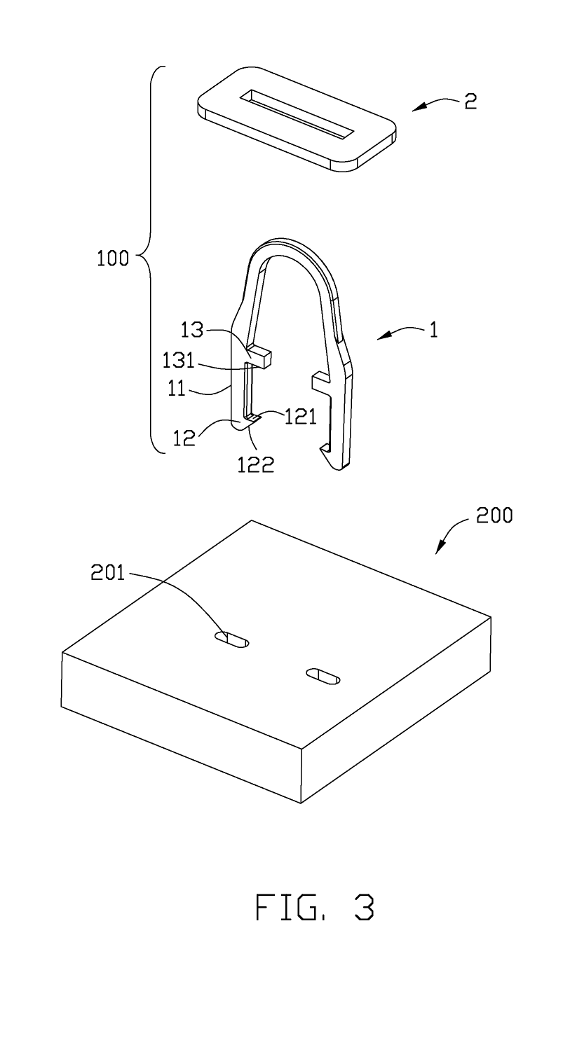

Referring to FIGS. 2 and 3, the fastening member 1 is formed into a U-shape. The fastening member 1 comprises a resilient link portion 14, a pair of legs 11 extending from two opposite distal ends of the resilient link portion 14, a pair of projections 12 extending inwardly from the tip end portions of the two legs 11 and a pair of stop portions 13 extending from the legs 11 and spaced from the respective projection 12. The two stop portions 13 parallel extend inwardly toward each other. Each projection 12 has an upwards slanted distal edge which defines a mating face 121. The distance between the mating face 121 of each projection 12 and the lower face 131 of the stop portion 13 is substantially identical to the thickness of the PCB 200. The width of each through hole 201 is a little larger than the width of each projection 12 so that the legs 11 of the fastening member 1 can readily pass through the through hole 201 of the PCB 200.

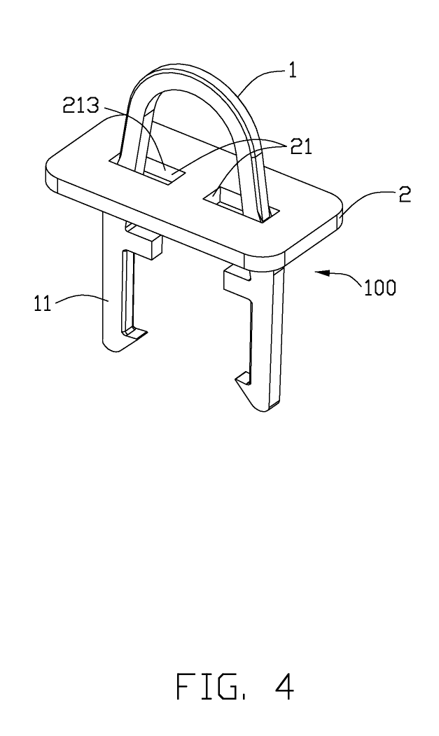

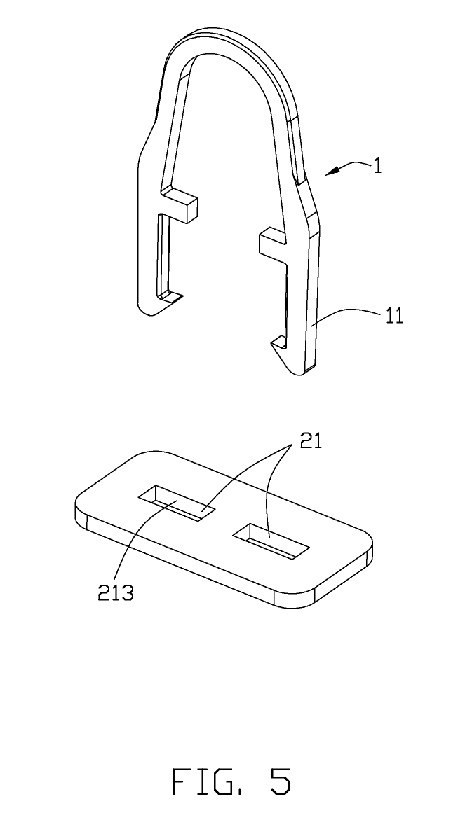

The locking member 2 is stamped from a planar metal and defines a longitudinal slot 21. Alternatively, the slot 21 can be divided into two holes 213 to respectively passing of the legs as shown in FIGS. 4 and 5.

During installation of the anchor 100 onto the PCB 200, the projections 12 pass through the through holes 201 of the PCB 200 respectively, until the stop portion 13 is stopped by the top surface 131 of PCB 200. Then the locking member 2 is mounted onto the fastening member 1 by the slot 21 passes through the resilient link portion 14. Since the longitudinal dimension of the slot is a litter smaller than the distance between the two legs so that the inner wall of the slot 21 press against the two legs 11 to shift the two legs inwards. Two projections 12 move toward each other and then abut against the bottom surface of the PCB 200 between the two through holes 201 in response to the shift of the legs 11. The anchor 100 is secured to the PCB 200 by the projection 12 and the stop portion 13, and no soldering process is required.

When the locking member 2 is to be removed from the fastening member 1, the fastening member 1 expands to its uncompressed state. Accordingly, the anchor 100 is easily removed from the PCB 200.

While a preferred embodiment in accordance with the present invention has been shown and described, equivalent modifications and changes known to persons skilled in the art according to the spirit of the present invention are considered within the scope of the present invention as described in the appended claims.

What is claimed is:

1. An anchor for attaching a heat sink to a PCB (printed circuit board) comprising:
an elastic fastening member comprising a resilient link portion, a pair of legs extending from two opposite ends of the resilient link portion, a pair of projections extending inwardly from tip end portions of the two legs and a pair of stop portions extending from the legs and spaced from the respective projection, the projections passing through a pair of through holes defined in the PCB respectively, each stop portion abutting against a top surface of PCB; and
a locking member defining at least one receiving hole;
wherein the locking member is mounted onto the fastening member to shift the two leg inward so that the projections abut against a bottom surface of the PCB.

2. The anchor as described in claim 1, wherein the two stop portions extending inwardly toward each other.

3. The anchor as described in claim 1, wherein width of the at least one through hole is a little larger than width of each projection.

4. A retaining device, including
first and second locking arms bridged by means of a resilient link portion;
each of the first and second locking arms including a pair of restraints spaced from each other and defining a preselected distance therebetween; and
a loop moveably enveloped onto the link portion so as to bring the restraints moving toward each other.

5. A retainer assembly comprising:
a printed circuit board defining opposite upper and bottom surfaces with first and second through holes extending therethrough in a vertical direction;
a retention device defining opposite first and second locking legs respectively extending through the corresponding first and second through holes, and linked to each other at top portions thereof via a bight which is configured to be a base where a heat sink clip is locked to;
a pair of hooks respective formed around bottom portions of said first and second locking legs, respectively;
an actuation device associated with the retention device and up and down moveable relative to the retention device between opposite first and second positions; wherein
when the actuation device is moved to the first position to urge the associated retention device, the hooks of said first and second locking legs are engaged at the bottom surface of the printed circuit board; when the actuation device is moved to the second position to free the associated retention device, the hooks of said first and second locking legs are disengaged from the bottom surface of the printed circuit board.

6. The retention assembly as claimed in claim 5, wherein the first position is closer to the printed circuit board than the second position.

7. The retention assembly as claimed in claim 5, wherein said first through hole and said second through hole are not communicative to each other transversely.

8. The retention assembly as claimed in claim 5, wherein said hooks are moved toward each other when said actuation device is moved to the first position.

9. The retention assembly as claimed in claim 5, wherein said actuation device is moveable between the first position and said second position in a parallel relation with said printed circuit board.

10. The retention assembly as claimed in claim 5, wherein each of said first and second locking legs is further equipped with the corresponding hook to restrain up and down movement of the corresponding locking leg.

11. The retention assembly as claimed in claim 5, wherein the actuation device forms a pair of through holes through which said first and second locking legs extend, respectively.

12. The retention assembly as claimed in claim 5, wherein the actuation device forms a through hole through which both said first locking legs and said second locking legs extend.
